(19) United States
(12) Patent Application Publication
(10) Pub. No.: US 2007/0208975 A1
(43) Pub. Date: Sep. 6, 2007

(54) PARALLEL ARCHITECTURE FOR LOW POWER LINEAR FEEDBACK SHIFT REGISTERS

(75) Inventors: RAJENDRA KATTI, FARGO, ND (US); ABDULLAH MAMUN, FARGO, ND (US)

Correspondence Address: JOHN P. O'BANION;O'BANION & RITCHEY LLP, 400 CAPITOL MALL SUITE 1550, SACRAMENTO, CA, 95814, US

(73) Assignee: NORTH DAKOTA STATE UNIVERSITY, FARGO, ND (US)

(21) Appl. No.: 11/558,721

(22) Filed: Nov. 10, 2006

Related U.S. Application Data
(63) Continuation of application No. PCT/US05/11234, filed on Apr. 4, 2005.
(60) Provisional application No. 60/570,226, filed on May 11, 2004.

(51) Int. Cl. G01R 31/28

(52) U.S. Cl. 714/727

(57) ABSTRACT

The present invention provides an apparatus and method for implementing low-power linear feedback shift registers (LFSR) that efficiently produce single or multiple outputs. In one case of single output generation the gates are permanently connected to the respective flip-flops reducing the number of switches necessary. In the case of multiple outputs the outputs are generated several clock cycles at once, which enables the frequency of operation to be reduced by a factor equal to the number of outputs produced at a time. In either case grouping is utilized for reducing the number of gates necessary and the power dissipation. The invention is applicable to a wide range of applications, including but not limited to data compression, encryption, communication, error correction, built-in self-test, and so forth.

### CROSS-REFERENCE TO RELATED APPLICATIONS

This application claims priority from, and is a 35 U.S.C. § 111(a) continuation of, co-pending PCT international application serial number PCT/US2005/011234, filed on Apr. 4, 2005, incorporated herein by reference in its entirety, which designates the U.S. and which claims priority from U.S. provisional application Ser. No. 60/570,226, filed on May 11, 2004, incorporated herein by reference in its entirety. Priority is claimed to each of the foregoing applications.

### STATEMENT REGARDING FEDERALLY SPONSORED RESEARCH OR DEVELOPMENT

This invention was made with Government support under Grant No. CCR-049523, awarded by the National Science Foundation. The Government has certain rights in this invention.

### NOTICE OF MATERIAL SUBJECT TO COPYRIGHT PROTECTION

A portion of the material in this patent document is subject to copyright protection under the copyright laws of the United States and of other countries. The owner of the copyright rights has no objection to the facsimile reproduction by anyone of the patent document or the patent disclosure, as it appears in the United States Patent and Trademark Office publicly available file or records, but otherwise reserves all copyright rights whatsoever. The copyright owner does not hereby waive any of its rights to have this patent document maintained in secrecy, including without limitation its rights pursuant to 37 C.F.R. § 1.14.

### BACKGROUND OF THE INVENTION

1. Field of the Invention

This invention pertains generally to shift registers, and more particularly to low-power linear-feedback shift register architectures having single or multiple outputs.

2. Description of Related Art

The ever-increasing density and complexity of today's digital designs demand low power consumption. This becomes more critical for components, which are widely utilized. The sequence generator circuit referred to as a Linear Feedback Shift Register (LFSR) is widely used in data compression, encryption, Built-in Self-Test (BIST), communication, error correction, and so forth.

For purposes herein, only Type I LFSRs (defined in “Digital Systems Testing and Testable Design” by M. Abromovici, M. A. Breuer, and A.D. Friedman, published by IEEE Press), which consists of a bank of D-flip-flops connected serially are considered. The output of some of these flip-flops (FFs) is XORed together and fed back to the first flip-flop. The conventional serial architecture of an LFSR with characteristic polynomial, F(x)=1+x²+x⁵, is shown in FIG. 1. Here the length of the LFSR (the number of flip-flops), which is denoted by N, is 5 and the number of taps or number of terms XORed, which is denoted by M, is 2. The level of power consumption in the serial architecture is high as all the flip-flops are clocked in every clock cycle while only one bit of information is generated per clock cycle. The output can be taken from the input or output of any flip-flop. When the output of i successive cycles are generated in one cycle then the LFSR is an i -output (or multiple output) LFSR.

One of the best-known low-power architectures for an LFSR was presented by M. Lowy in “Parallel Implementation of Linear Feedback Shift Registers for Low Power Applications”, IEEE Transactions on Circuit and Systems II: Analog and Digital Signal Processing, Vol. 43, pp. 458-466. The reference from M. Lowy is referred to herein as the “Lowy reference” or Lowy architecture”. In the Lowy architecture, the output of only one flip-flop changes every clock cycle, thereby reducing power dissipation.

However, extra circuitry has to be added to assure that the output of only one flip-flop changes with each clock cycle. The above architecture is described by FIG. 2 and referred to as to the Lowy architecture, in which signal Tᵢ=(i=1, 2, . . . N) is obtained from an N -phase generator (e.g., a Johnson counter in combination with AND gates). The value of Tᵢ is logic-1 in clock cycle i mod N and logic-0 in all other clock cycles. From FIG. 2 it can be seen that the outputs of flip-flops 2 and 5 are XORed together in cycle 1 and the result is stored in flip-flop 5 at the clock edge of cycle 2. This happens because the switches at the output of flip-flops 2 and 5 are turned on by T1. In cycles 2, 3, 4, and 5 respectively, the outputs of flip-flops (1, 4), (5, 3), (4, 2), and (3, 1) are XORed together and stored in flip-flops 4, 3, 2, and 1 respectively, at the clock edges of cycles 3, 4, 5, and 1 respectively. It should be noted that the output of the XOR gate is the output of the LFSR. The operation of the LFSR is described by Table 1.

Table 1 shows that the result of XORing the outputs of flip-flops 2 and 5 in cycle 1 is stored in flip-flop 5. However, this result is stored in flip-flop 5 in the beginning of clock cycle 2 and not in cycle 1 as shown in the table, which applies to all clock cycles. The switches that are turned on by more than one Tᵢ are controlled by the ORing of these Tᵢ signals. Consequently, a bank of OR gates may be necessary for controlling the activity of the switches. In FIG. 2, there are shown 4 switches controlled by 2 Tᵢ's each and hence 4, 2-input OR gates are required. Therefore, the complete single output LFSR described by the Lowy architecture consists of an N -phase generator, (N+M) switches, N flip-flops, (M−1) 2-input XOR gates, and a maximum of (N+M), M-input OR gates.

A two-output LFSR with characteristic polynomial 1+x²+x⁵, is also described by the Lowy reference within a circuit which consists of (N+M)+2N more switches than the single output case and each flip-flop is clocked by two clock signals. Obtaining more than two outputs results in requiring an excessive number of switches and phase clocks.

Linear feedback shift registers (LFSR) are important building blocks utilized in data compression, signal processing, encryption, self-test, communications, error correction, and other application areas.

Accordingly, many benefits can be derived by reducing the power consumption of LFSR circuits without a corresponding speed penalty. The present invention fulfills that need and overcomes drawbacks of previous methods.

### BRIEF SUMMARY OF THE INVENTION

Linear feedback shift register (LFSR) circuits and method are described for implementing any desired polynomial function. The inventive circuit utilizes a string of N flip-flops which are connected with gates and switching to generate a polynomial at reduced power levels, in comparison with clocking all flip-flops at each output bit transition. The embodiments of the invention utilize grouping of the terms to reduce the hardware and power dissipation. Two general types of embodiments are described.

In a first form of LFSR the N flip-flops are interconnected with logic gates, preferably exclusive-OR (XOR) gates, which are permanently attached to the respective flip-flops forming the stages of the shift register and consequently reducing the number of necessary switches. The switches are used for selecting which flip-flop outputs reach the output of the circuit. Different clock phase signals are used for clocking the different stages of the shift register thereby reducing operating power. This LFSR method requires only N/2 XOR gates for implementing even order Hamid's polynomial functions, or a maximum of N XOR gates for implementing any arbitrary polynomial function.

In a second form of LFSR the output from the N flip-flops is switched through at least one switch per flip-flop output into the a plurality of gate inputs, preferably XOR gates. The outputs from the XOR gates comprise multiple circuit outputs and also provide signals for driving the data inputs on groups of the flip-flops. The flip-flops are clocked in groups by a number of phase clocks equal to the number of groups within the LFSR.

The present invention provides apparatus and methods by which highly efficient LFSR circuits can be implemented having one or multiple outputs. The invention is amenable to being embodied in a number of ways, including but not limited to the following descriptions.

One embodiment of the present invention can be generally described as an apparatus for generating a multiple output digital sequence, comprising: (a) a plurality of N flip-flops forming a linear feedback shift register (LFSR) having a characteristic polynomial, 1+x^{k}^{₁}+x^{k}^{₂}+ . . . +x^{k}^{_{M−1}}+x^{N}, with k₁<k₂< . . . <k_{M-1}<N and M taps; (b) a plurality of gates (i.e., XOR gates) coupled to select flip-flops in the LFSR based on combining the cycles of multiple flip-flops within the LFSR into flip-flop groups in which none of the outputs of the flip-flops within each flip-flop group are needed as input until subsequent cycles; and (c) a separate phase clock signal connected to each flip-flop or group of flip-flops. The XOR gates can be either permanently coupled between flip-flops in the LFSR, or coupled between switches on the outputs of the flip-flops. The combining of flip-flops into flip-flop groups allows slowing the clock rate to the LFSR in response to the fewer number of phases necessary and in response to having the outputs from multiple flip-flops available simultaneously. If a single output is desired, then a multiplexer, or other form of signal selector, is coupled to the shift register or gates for selecting the bits of the output signal.

An LFSR according to the invention which utilizes non-switched XOR connections requires a maximum of N/2 exclusive-OR gates to implement an even order Hamid polynomial, or N exclusive-OR gates for implementing any arbitrary polynomial. In one aspect of the invention, the clock signals are supplied as a first clock signal and a second clock signal which is the inverse of the first clock signal, such that an N -phase clock generator is not necessary.

An LFSR according to the invention which utilizes switched XOR gates can provide multiple outputs which comprise up to k₁ outputs in each clock cycle, having a maximum of k₁ gates (i.e., XOR) required for generating k₁ outputs. The LFSR is configured to be driven by a maximum of ┌N/k₁┐ phases from a phase generator; and the maximum of number of switches required for the implementation is less than (N+M), where M is the number of taps in the LFSR.

The apparatus can generate the digital sequence at reduced power levels in response to the N flip-flops not being clocked in each clock cycle while only generating a single bit of information per clock cycle as in a conventional LFSR. The gates preferably comprise exclusive-OR (XOR) gates. The data inputs of at least two different flip-flops within the LFSR are driven by the outputs of at least two different gates. Digital switches are used for routing flip-flop outputs to gate inputs, or alternatively for selecting the output when the gates are permanently coupled to the flip flops, or a combination thereof. The outputs of several of the LFSR flip-flops are available simultaneously. A multiplexer circuit, or set of switches, can be coupled to the multiple outputs if a single output is required.

Another embodiment of the invention can be generally described as an apparatus for generating a digital sequence, comprising: (a) a plurality N flip-flops forming a linear feedback shift register (LFSR) having a characteristic polynomial, 1+x^{k}^{₁}+x^{k}^{₂}+ . . . +x^{k}^{_{M−1}}+x^{N}, with k₁<k₂< . . . <k_{M-1}<N and M taps for up to k₁ outputs in each clock cycle; (b) at least one switch coupled to the output of each flip-flop; (c) a plurality of exclusive-OR (XOR) gates receiving inputs through switches from the flip-flops and having outputs coupled to the data inputs of the flip-flops; (d) at least two separate phase clock signals coupled to the clock inputs of flip-flops, the number of necessary phase clocks and the connection of the phase clocks to the clock inputs determined in response to combining the cycles for multiple flip-flops when none of the outputs of those multiple flip-flops are needed as input until subsequent cycles.

In the LFSR the outputs of at least two different XOR gates drive the data inputs of at least two different flip-flops. A multiplexer may be utilized for creating a single output from the output of the multiple XOR gates. It should be appreciated that with this embodiment an N -phase clock generator is not necessary for driving said separate clock signals.

The combination of cycles in this embodiment reduces the clock rate and lowers power dissipation by a factor of k₁. In addition, the hardware requirements are reduced to where a maximum of k₁ XOR gates are required for generating k₁ outputs, the LFSR can be driven requiring a maximum of ┌N/k₁┐ phases from a phase generator, and the maximum number of switches required to implement the LFSR is less than (N+M), where M is the number of taps in the LFSR.

An embodiment of the invention may also be generally described as a method of generating a digital sequence, comprising: (a) forming N flip-flops for interconnection into a linear feedback shift register (LFSR) having a characteristic polynomial, 1+x^{k}^{₁}+x^{k}^{₂}+ . . . +x^{k}^{_{M−1}}+x^{N}, with k₁<k₂< . . . <k_{M-1}<N and M taps for up to k₁ outputs in each clock cycle; (b) determining the flip-flop outputs that are XORed and into which flip-flop the XOR output is stored for each clock cycle; (c) grouping the flip-flops by combining every k₁ clock cycles into one clock cycle so that each clock cycle produces k₁ outputs; (d) forming a switch network for each of the k₁, M-input XOR gates; (e) interconnecting the XOR gates and switches in response to the determined grouping; and (f) generating phase clocks for driving the clocks in each flip-flop group and control signals for activating any switches which are common between the phase clocks.

In this embodied method at least one switch is coupled between the output of each flip-flop and the input of at least one XOR gate. As the switches may be used for multiple outputs, control signals are generated by ORing the phase clocks for driving the state of the switches.

Embodiments of the present invention can provide a number of beneficial aspects which can be implemented either separately or in any desired combination without departing from the present teachings.

An aspect of the invention is to allow implementing low-power single and multiple output LFSR circuitry with less hardware, fewer clocks, and an overall reduction in power dissipation.

Another aspect of the invention is to allow implementing low-power single output LFSR circuitry with fewer switches, or eliminating switches altogether.

Another aspect of the invention is to implement low-power LFSR circuitry in which the gates are permanently coupled to the respective flip-flops in order to achieve a reduction or elimination of switches.

Another aspect of the invention is to implement low-power LFSR circuitry in which the number of XOR gates required is N/2 for even order Hamid's polynomial and N for other polynomials.

Another aspect of the invention is to implement low-power LFSR circuitry in which any arbitrary polynomial can be implemented.

Another aspect of the invention is to implement low-power LFSR circuitry in which the operation of a portion of the clock cycles (i.e., two or three groups of flip-flops) can be performed simultaneously as the operands do not depend on the result of these cycles, thus reducing the number of necessary clock phases.

Another aspect of the invention is to implement low-power LFSR circuitry in which the clock generator comprises the combination of a clock signal and its inverse.

Another aspect of the invention is to implement low-power LFSR circuitry which does not require multi-clock flip-flop circuits.

Another aspect of the invention is to provide an architecture from which low-power LFSR circuitry having more than two outputs can be practically implemented, these being impractical previously.

Another aspect of the invention is to implement low-power LFSR circuitry having more than two outputs without the need of doubling the number of gates when doubling the number of outputs.

Another aspect of the invention is to implement multi-output low-power LFSR circuitry having characteristic polynomial, 1+x^{k}^{₁}+x^{k}^{₂}+ . . . +x^{k}^{_{M−1}}+x^{N}, with k₁<k₂< . . . <k_{M-1}<N, that can generate k₁ outputs in each clock cycle.

Another aspect of the invention is to implement multi-output low-power LFSR circuitry in which only k₁ XOR gates are required for generating k₁ outputs.

Another aspect of the invention is to implement multi-output low-power LFSR circuitry in which only ┌N/k₁┐ clock phases are required.

Another aspect of the invention is to implement multi-output low-power LFSR circuitry in which the number of switches needed is less than (N+M).

Another aspect of the invention is to implement multi-output low-power LFSR circuitry in which clock frequency and power dissipation is reduced significantly, such as by a factor of k₁.

Another aspect of the invention is to implement a low-power LFSR circuit having multiple outputs which are converted, such as with multiplexer and latches, to a single output LFSR with less hardware and power dissipation than required by conventional single output LFSR circuits.

Another aspect of the invention is to implement multi-output low-power LFSR circuitry having reduced power dissipation within phase generators, gates, and flip-flops.

Another aspect of the invention is to implement multi-output low-power LFSR circuitry which generates more distinct patterns than generated by conventional circuitry (i.e., as described by Hamid and Chen reference) making the present invention more suitable for built-in self-test (BIST) applications and other pattern depth related applications.

A still further aspect of the invention is to allow replacement of conventional high power LFSR circuitry in which each flip-flop is clocked every cycle with low-power circuitry without significantly increasing circuit complexity. Further aspects of the invention will be brought out in the following portions of the specification, wherein the detailed description is for the purpose of fully disclosing preferred embodiments of the invention without placing limitations thereon.

### BRIEF DESCRIPTION OF THE SEVERAL VIEWS OF THE DRAWING(S)

The invention will be more fully understood by reference to the following drawings which are for illustrative purposes only:

FIG. 1 is a schematic of a conventional serial LFSR implementation of polynomial F(x)=1+x²+x⁵ which exhibits a high level of power dissipation because every flip-flop receives the same clock signal, and is clocked for each bit of output.

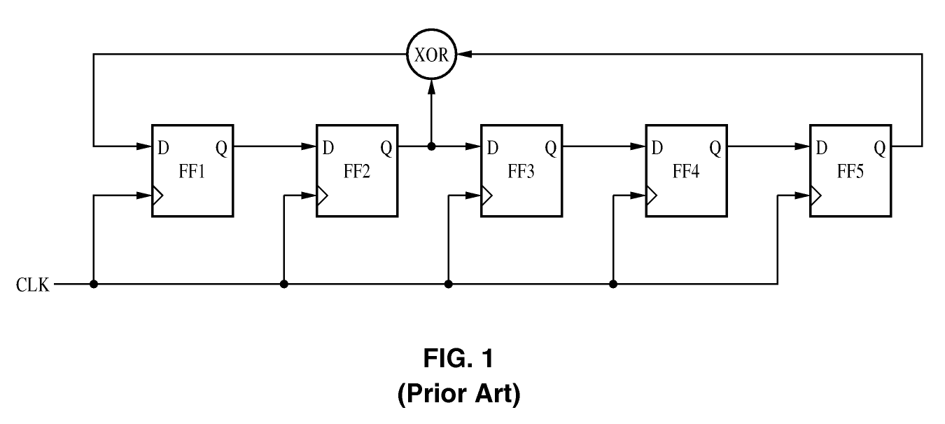

FIG. 2 is a schematic of a conventional low-power LFSR implementation of polynomial F(x)=+x²+x⁵ using a number of switches to reduce power consumption.

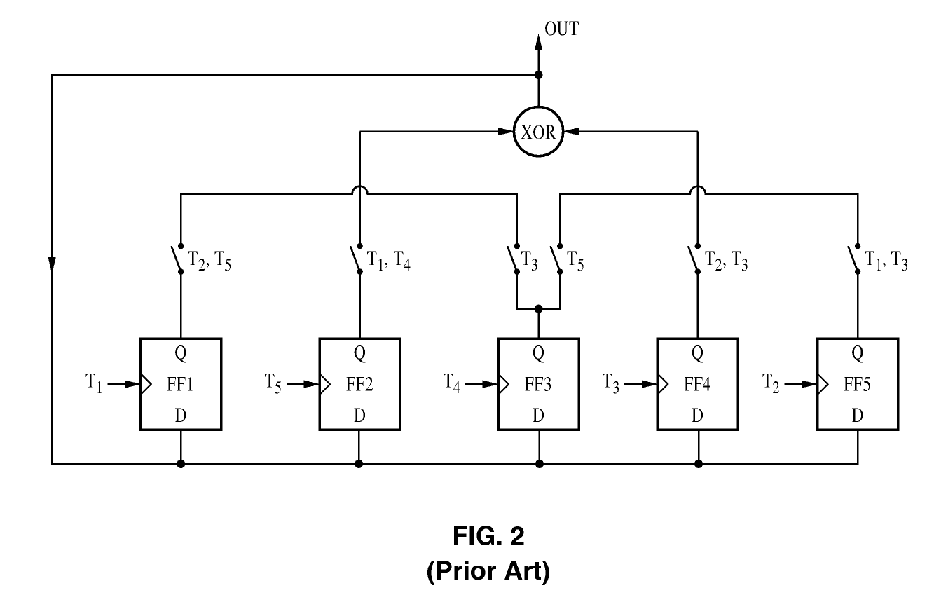

FIG. 3 is a schematic of a single output low-power LFSR implementation of polynomial F(x)=1+x³+x⁶ according to an aspect of the present invention.

FIG. 4 is a schematic of a single output low-power LFSR implementation of polynomial F(x)=1+x⁴+x⁷ according to an aspect of the present invention.

FIG. 5 is a schematic of a single output low-power LFSR implementation of polynomial F(x)=1+x⁴+x⁵+x⁶+x⁷ according to an aspect of the present invention.

FIG. 6 is a schematic of a multiple output low-power LFSR implementation of polynomial F(x)=1+x³+x⁶ according to an aspect of the present invention.

FIG. 7 is a schematic of a multiple output low-power LFSR implementation of polynomial F(x)=1+x²+x⁵ according to an aspect of the present invention.

FIG. 8 is a schematic of a multiple output low-power LFSR implementation of polynomial F(x)=1+x³+ x⁴+x⁷+x¹² according to an aspect of the present invention.

FIG. 9 is a flowchart of a method of implementing a multiple output LFSR according to an aspect of the present invention.

### DETAILED DESCRIPTION OF THE INVENTION

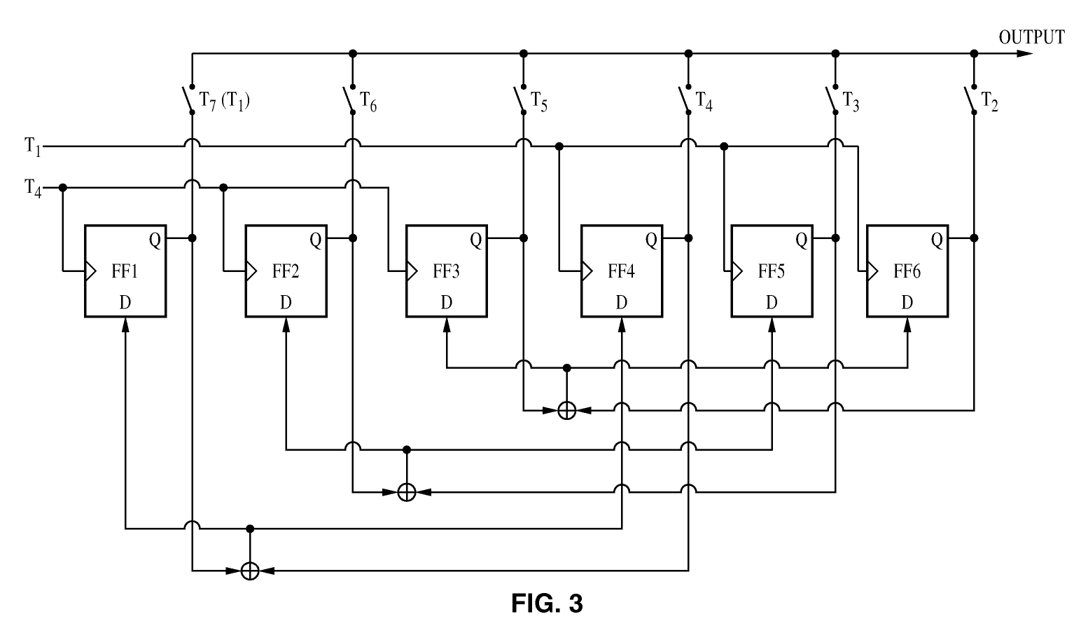

Referring more specifically to the drawings, for illustrative purposes the present invention is embodied in the apparatus generally shown in FIG. 3 through FIG. 9. It will be appreciated that the apparatus may vary as to configuration and as to details of the parts, and that the method may vary as to the specific steps and sequence, without departing from the basic concepts as disclosed herein.

1. Low-Power Single Output LFSR Architecture.

In one embodiment of the present inventive low-power LFSR architecture, XOR gates are permanently connected to the respective flip-flops, thereby reducing the number of switches needed. The number of XOR gates required is N/2 for even order Hamid's polynomial and N for other polynomials.

Considering the polynomial F(x)=1+x³+x⁶, Table 2 shows the storing method of calculated results in order to obtain the parallel implementation. In cycle 1, XOR result of flip-flops 3 and 6 (which is calculated in the previous cycle) is stored in flip-flop 6. Similarly in clock cycle 2, 3, 4, 5, and 6 XOR results of flip-flops (2, 5); (1, 4); (6, 3); (5, 2); and (4,1) should be stored in flip-flop 5, 4, 3, 2, and 1 respectively. It should be noted that XOR results of flip-flop (3, 6) are same as XOR results of (6, 3). Therefore, the number of XOR gates needed is 6/2=3.

FIG. 3 illustrates an example of an LFSR for the polynomial F(x)=1+x³+x⁶ constructed according to Table 2. In general, for even order polynomial of the form F(x)=1+x^{N/2}+x^{N}, N/2 XOR gates are needed.

For odd order polynomials, LFSRs according to this embodiment with the unswitched gates have been tested with both ceiling and floor values and a list of polynomials given within a paper by M. Hamid and C. Chen entitled “A Note to Low-Power Linear Feedback Shift Registers” within IEEE transactions on Circuits and Systems II: Analog and Digital Signal Processing, Vol. 45, No. 9, pp. 1304-1307, September 1998. First the example polynomial with N=7, F(x)=1+x⁴+x⁷ is considered, with Table 3 shows the storing procedure in order to obtain the parallel implementation.

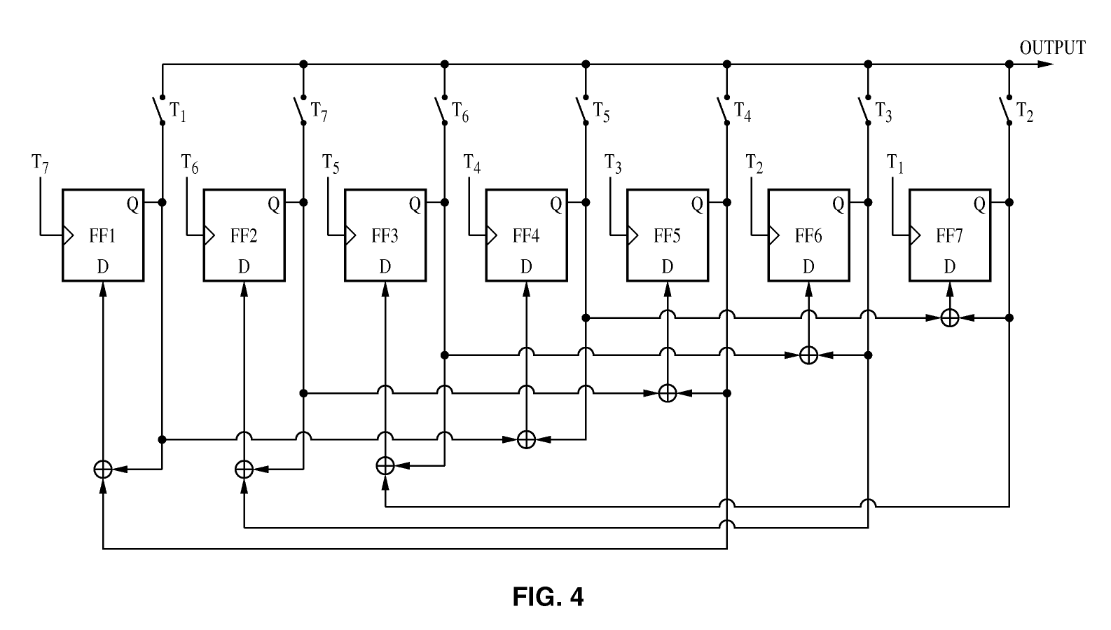

FIG. 4 illustrates an example of an LFSR for the polynomial F(x)=1+x⁴+x⁷ constructed from Table 3. It is evident that the number of XOR gates is 7, which is equal to N.

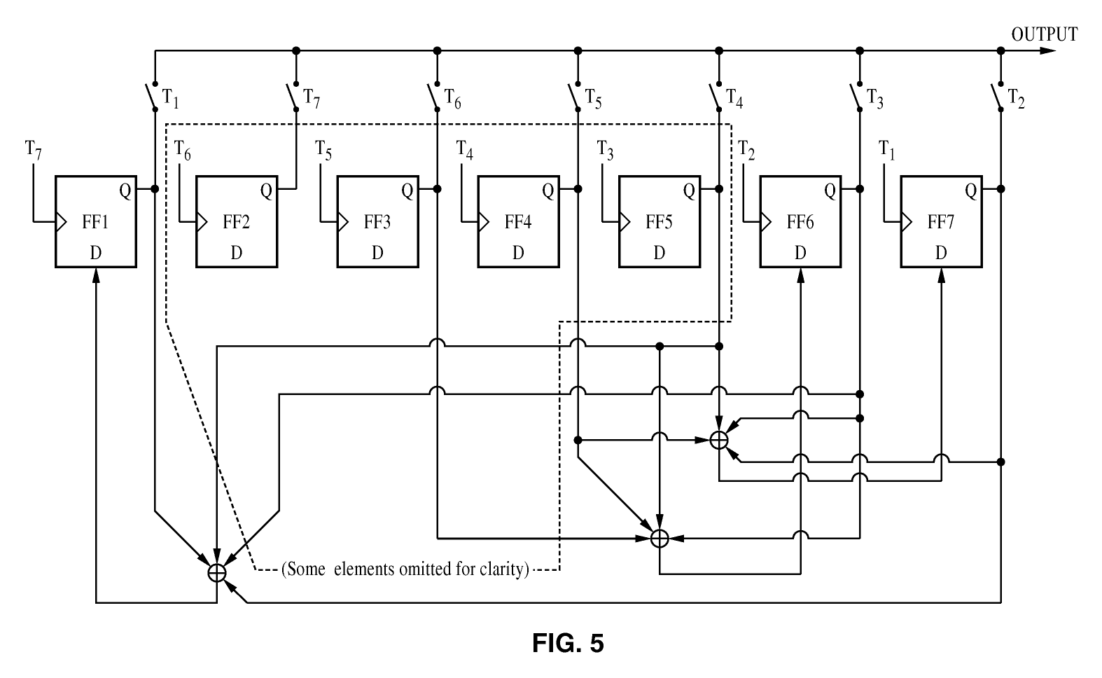

FIG. 5 illustrates an example of an LFSR for an arbitrary primitive polynomial F(x)=+x⁴+x⁵+x⁶+x⁷, constructed from the storing process detailed in Table 4. To simplify the drawing, and fit it on the page, some of the XOR gates and connections are omitted, these omitted sections are encircled with a dashed line.

2. Low-Power Multiple Output LFSR Architecture.

The proposed method can also be used to generate multiple outputs. Let us consider the polynomial F(x)=1+x³+x⁶. From Table 2, it is evident that operation of clock cycle 1, 2, and 3 can be performed simultaneously as the operands do not depend on the result of these cycles. Similarly, operations of clock cycle 4, 5, and 6 can be performed simultaneously, wherein Table 2 can be rearranged, to create Table 5.

Table 5 shows that only two clock cycles are needed to do the operation instead of 6 clock cycles. In the first cycle XOR results of flip-flops (3, 6); (2, 5); and (1, 4) (that are all calculated in the previous cycle) are stored in flip-flop number 3, 2, and 1 respectively. In the next cycle XOR results of flip-flops (6, 3); (5, 2) and (4, 1) are sorted in flip-flop number 3, 2, and 1 respectively.

From Table 5 it is evident that only 3 XOR gates are required as XOR connections required in the two cycles are symmetrical, such as (3, 6) and (6, 3) which use the same XOR connection.

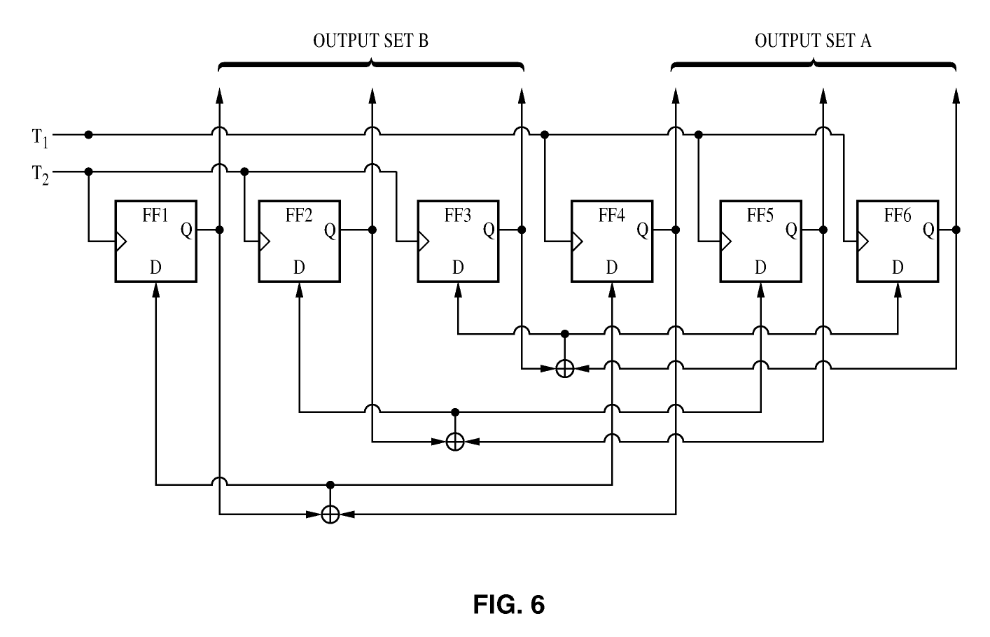

FIG. 6 illustrates a circuit constructed according to Table 5, and shows N/2 outputs are generated in each clock cycle. The clock T2 can be generated by inverting T1, wherein there is no need to provide additional multiphase generator circuitry as required by the design described in the Lowy reference. Outputs A and B generate the XOR results of (3, 6); (2, 5); (1, 4) and (6, 3); (5, 2); and (4, 1) respectively. Important aspects of this structure include but are not limited to the following:
(a) Circuit is readily implemented and generates N/2 outputs. Using previous methods having greater than two outputs was impractical due to complexities involved.
(b) Only N/2 XOR gates are required within the LFSR.
(c) No need to have clock generator create N phases. Fewer phases are necessary, such as only two phases, a clock (T1) and its inversion (T2) can be generated by inverting the clock.
(d) No need to have multi-clock flip-flops as required by earlier methods, such as described by the Hamid and Chen reference.
(e) Number of switches needed is less than (N+M). By contrast in the Lowy architecture the maximum number of switches is given by the number of outputs x(2N+M).
(f) No extra XOR gates are required for multiple outputs, whereas previous methods require doubling the XOR gate requirement for double output generation.
(g) As the clock rate is reduced by N/2, supply voltage can be reduced which in turn reduces power consumption.

The architecture of the present invention for an LFSR having characteristic polynomial, 1+x^{k}^{₁}+x^{k}^{₂}+ . . . +x^{k}^{_{M−1}}+x^{N}, with k₁<k₂< . . . <k_{M-1}<N, can generate k₁ outputs in each clock cycle. Therefore, the number of M-input XOR gates needed is k₁. Consequently, the phase generator needs to generate only ┌N/k₁┐ phases instead of N phases as required in prior architectures. The number of switches needed is less than (N+M). Since k₁ outputs are available at a time, the clock frequency and hence the power dissipated reduces by a factor of k₁.

Therefore, the architecture of the present invention can be implemented with less hardware and lower power dissipation than that described by the Lowy architecture. The multiple output LFSR described above can be easily converted to a single output LFSR using a multiplexer and latches, which operate at k₁ times the frequency of the multiple output LFSR. However, since the multiplexer and latches are the only components operating at the higher frequency and they have low power dissipation, converting to a single output LFSR is readily achieved.

Describing another example embodiment of a characteristic polynomial 1+x²+ x⁵ as given by Table 1. The contents of the flip-flops are referred to at cycle i as the state in cycle i. From Table 1 it can be seen that in cycle 1 the outputs of flip-flops 2 and 5 are XORed together and stored in flip-flop 5 at the clock edge of cycle 2. This new state of flip-flop 5 is used in cycle 3 when it is input to an XOR gate. Similarly, in cycle 2 flip-flops 1 and 4 are XORed together and stored in flip-flop 4 at the clock edge of cycle 3. This new state of flip-flop 4 is used again in cycle 4. This implies that both cycles 1 and 2 can be performed simultaneously because in both these cycles only the initial state of the flip-flops is utilized. Similarly, cycles 3 and 4 can be performed simultaneously and cycle 5 has to be performed by itself. Cycles 1 and 2, change the state of flip-flops 5 and 4, which are then used in cycles 3 and 4. Cycles 3 and 4 change the state of flip-flops 3 and 2, which are then used in cycle 5. This new operation is summarized in Table 6, in which two clock cycles of Table 1 are shown as a single clock cycle.

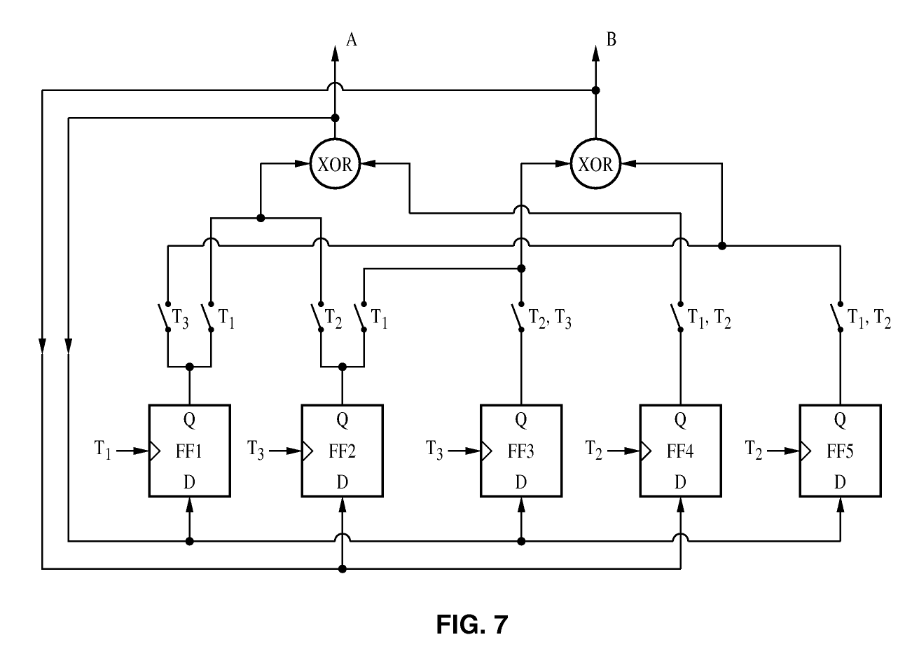

FIG. 7 illustrates an example circuit constructed according to Table 6, in which the output of the LFSR is the output of the XOR gates. It should be noted that in cycle 1 and 2, two outputs are obtained, and in cycle 3 only one output is obtained.

From the previous example it is seen that the number of outputs that can be obtained is two, which is the exponent of x² in 1+x²+x⁵. The total number of phases which are generated by the phase-generator is then ┌5/2┐, where 5 is the degree of the characteristic polynomial and 2 is the lowest, non-zero exponent of a term in the characteristic polynomial. The number of switches required in our implementation is always less than (N+M) times the number of outputs. In the above example the maximum number of switches value determined was 14, whereas in the actual implementation only 7 switches were required. An implementation according to the Lowy architecture would require 22 switches, which is always less than (2N+M) times the number of outputs.

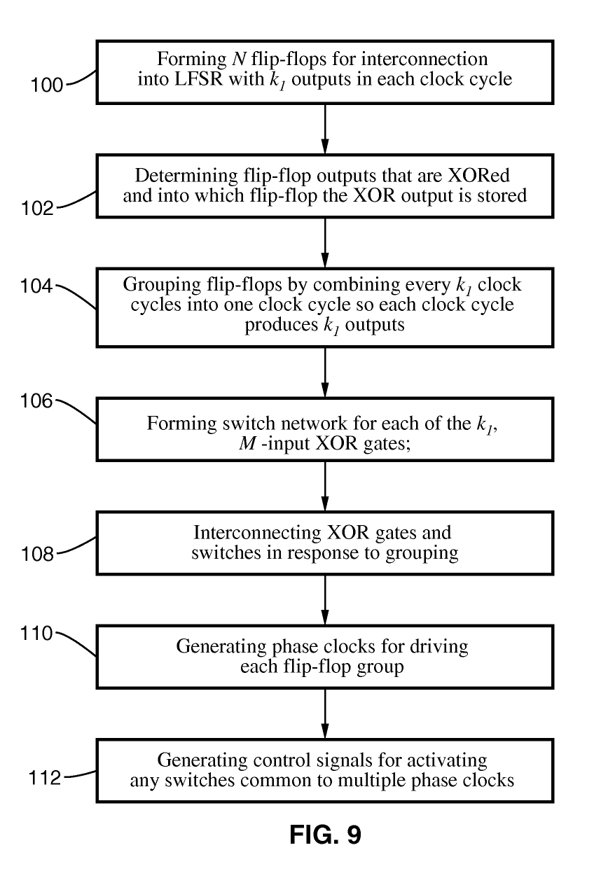

FIG. 9 depicts a general method for the design of an LFSR with characteristic polynomial 1+x^{k}^{₁}+x^{k}^{₂}+ . . . +x^{k}^{_{M−1}}+x^{N}, with k₁<k₂< . . . <k_{M-1}<N. As represented by block 100, N Flip-flops are formed for interconnection into an LFSR. In block 102 it is determined which flip-flop outputs are XORed and into which flip-flop the XOR is being output. This results in creating a table similar to Table 1 for the operation of the LFSR. A grouping is performed as per block 104, based on combining every k₁ clock cycles into one clock cycle so that each clock cycle produces k₁ outputs. A switch network is then formed as per block 106 for each of the k₁, M-input XOR gates. It should be noted that the i th XOR gate produces the i th output, amongst the k₁ outputs produced in each cycle. Then as per block 108 the XOR gates and switches are interconnected in response to the grouping. In block 110 and 112 are depicted the generation of the phase clocks, one for each group, and control signals as necessary for controlling switches which are used across multiple phase clocks. The control logic for example, may comprise OR gates configured for combining phase clocks to drive select switches.

In this embodiment, the hardware required can be generally summarized as:

1. an ┌N/k₁┐ phase generator.

2. Approximately ┌N/k₁┐ OR gates, with each OR gate having an average number of inputs equal to M/ Dₐᵥ ┌N/k₁┐. Wherein Dᵢ is the number of distinct inputs that are input to XOR gate i in ┌N/k₁┐ clock cycles. For example in Table 6 it can be seen that one of the XOR gates receives inputs from flip-flops (2, 5), (5, 3), and (3, 1) in cycles 1, 2, and 3 respectively. Therefore the number of distinct inputs it receives in these three cycles is, D₁=4, and they are the outputs of flip-flops 2, 5, 3, and 1. Note that the i^{th} entry in row 2 of all columns refer to inputs to XOR gate i. Therefore, from Table 6 it can be seen that the second entry in row 2 of all columns are (1, 4) and (4, 2) making D₂=3. The average of all the D's is Dₐᵥ, such as given by

$${D}_{av} = \frac{1}{{k}_{1}} {\sum }_{i = 1}^{{k}_{1}} {D}_{i} .$$

Each XOR gate has M inputs in every clock cycle. Every ┌N/k₁┐ clock cycles these inputs repeat. Therefore, M┌N/k₁┐ inputs are applied to an XOR gate over ┌N/k₁┐ clock cycles.

However only Dₐᵥ distinct inputs exist over ┌N/k₁┐ cycles. This implies that over ┌N/k₁┐ cycles each XOR gate input has a flip-flop output connected to it M/ Dₐᵥ┌N/k₁┐ times. Therefore the switch connected to this input must be turned on M/Dₐᵥ┌N/k₁┐ times. Thus the OR gate controlling the switch must have M/Dₐᵥ┌N/k₁┐ phases (or Tᵢ's) as its input.

3. Approximately

$${k}_{1} {D}_{av} = {\sum }_{i = 1}^{{k}_{1}} {D}_{i}$$

switches. At XOR gate i's inputs, Dᵢ distinct flip-flop outputs arrive over ┌N/k₁┐ cycles. For each distinct flip-flop output there must be a switch that connects it to the XOR gate input. Since there are k₁ XOR gates the total number of switches is given by

$${k}_{1} {D}_{av} = {\sum }_{i = 1}^{{k}_{1}} {D}_{i} .$$

4. N flip-flops.

5. k₁, M-input XOR gates.

There is a distinct contrast in the requirements between these different architectures. The requirements listed above for the new architecture compare very favorably with the requirements of the Lowy reference, listed as follows:

1. An N phase generator.

2. A maximum of k₁(N+M), M-input OR gates.

3. A maximum of k₁(2N+M) switches. A maximum of (N+M)

switches are needed for the input of each XOR gates and since there are k₁ XOR gates the total number of switches at the inputs of the XOR gates is k₁ (N+M). The output of each XOR gate is connected to the N flip-flops via N switches implying that k₁ N switches are connected to the outputs of all the XOR gates. Thus the total number of switches required is k₁(2N+M).

4. N flip-flops.

5. k₁, M-input XOR gates.

By choosing the appropriate characteristic polynomial, the method of the present invention leads to a major reduction in the number of required OR gates and switches. Since an N phase generator has N/2 flip-flops with N two-input NAND gates, an implementation according to the present invention of a ┌N/k₁┐ phase generator requires only ½┌N/k₁┐ flip-flops and ┌N/k₁┐ two-input NAND gates. The number of LFSR flip-flops and XOR gates however still remains the same. The following lemma states a relationship between the number of switches in the architecture of the present invention and the Lowy architecture.

Lemma 1: The maximum number of switches in the present inventive architecture is less than the maximum number of switches according to the Lowy architecture.

Proof: The number of switches in the present inventive architecture is

$${k}_{1} {D}_{av} = {\sum }_{i = 1}^{{k}_{1}} {D}_{i} .$$

The average number of distinct flip-flop outputs connected to an XOR gate over ┌N/k₁┐ cycles is referred to as Dₐᵥ. Since there are only N flip-flops the maximum value of Dₐᵥ is N. Therefore the maximum number of switches in this new architecture is k₁N, which is less than the maximum number of switches required by the Lowy architecture which is k₁(2N+M).

3. Power Dissipation Comparison of Architectures.

The following section considers power dissipation and compares the architecture of the present invention with that of the described Lowy reference. Equations are derived for the power dissipated for the phase generator, OR gates, flip-flops, and XOR gates. For dynamic power calculation, industry recognized notations and assumptions are utilized to make the comparisons simple, for example as described within a paper by M. Hamid and C. Chen entitled “A Note to Low-Power Linear Feedback Shift Registers” within IEEE transactions on Circuits and Systems II: Analog and Digital Signal Processing, Vol. 45, No. 9, pp. 1304-1307, September 1998. The worst-case dynamic power is given by the equation:

$$P = \frac{1}{{t}_{P}} \times {C}_{total} \times {V}_{dd}^{2} \times ( percentage activity )$$

where t_{P} is the clock period, C_{Total} is the total capacitance driven by the gate outputs, V_{dd} is the supply voltage, and the percentage activity is 50%.

Other notations used in the calculations are as follows.

P_{FF}=power dissipation of the D flip-flop with 1 output capacitance.

P_{clock}=the clock power dissipated by each flip-flop.

P_{XOR}=power dissipation of an XOR gate with 1 output capacitance.

P_{OR}=power dissipation of an OR gate with 1 output capacitance.

P_{AND}=power dissipation of an AND gate with 1 output capacitance.

Pₘᵢₙ=power dissipation due to load of the source capacitance of a minimum size transistor.

P_{INV}=power dissipation of an inverter with 1 output capacitance.

N=Number of stages.

M=Number of taps.

3.1 Phase Generator Power.

Using a similar analysis as described by Lowy (which allows a valid comparison to be made) the power dissipation in the phase generator is given by:

$${P}_{1} = 2 {P}_{FF} + 2 {P}_{AND} ( \frac{M}{{D}_{av}} ⌈ \frac{N}{{k}_{1}} ⌉ ) + \frac{1}{2} ⌈ \frac{N}{{k}_{1}} ⌉ {P}_{clock}$$

In the above expression the term M/Dₐᵥ┌N/k₁┐ is the load on the AND gates, which is the number of OR gates to which the output of an AND gate is connected. In order to simplify calculations we choose to include the clock power dissipation in the flip-flop power dissipation just as described by Hamid and Chen. The phase generator power dissipation is now given by:

$${P}_{1} = 2 {P}_{FF} + 2 {P}_{AND} ( \frac{M}{{D}_{av}} ⌈ \frac{N}{{k}_{1}} ⌉ )$$

The power dissipated by the phase generator as described by Lowy is:
P_{IL}=2P_{FF}+2P_{AND}(k₁M+k₁)

The term (k₁M+k₁) is the load on an AND gate which is k₁ M OR gates and k₁ switches providing inputs to the flip-flops.

3.2 OR Gate Power.

In the architecture of the present invention and that of the Hamid and Chen reference during each clock cycle k₁ M switches are activated. Therefore the power dissipated by the OR gates is P2=k₁ M P_{OR}.

3.3 Flip-flop Power.

In the architecture of the present invention each flip-flop is connected to an average of k₁Dₐᵥ/N switches and only k₁ of the flip-flops change state in a given clock cycle. Therefore the power dissipated by the flip-flops is

$${P}_{3} = \frac{1}{2} {k}_{1} {P}_{FF} + \frac{1}{2} \frac{{k}_{1} {D}_{av}}{N} {P}_{FF} .$$

The “½” in the power in this and other expressions that follow, accounts for the fact that the flip-flop changes state only 50% of the time (percentage activity of the flip-flop). For the Lowy architecture each flip-flop is connected to approximately k₁ switches (this assumes that (N+M)/N=1, as put forth in Lowy) and k₁ flip-flops change state each cycle, therefore the power dissipated by the flip-flops is given by

$${P}_{3 L} = \frac{1}{2} {k}_{1} {P}_{FF} + \frac{1}{2} {k}_{1} {P}_{FF} .$$

3.4 XOR Gate Power.

In the architecture of the present invention k₁ XOR gates are connected to k₁ flip-flops, therefore the power dissipated by the XOR gates is generally given by P₄=½k₁²P_{XOR}. If an inverter were to drive each of the N flip-flops, then the power dissipated by the XOR gates would be

$${P}_{4} = \frac{1}{2} {k}_{1} {P}_{XOR} + \frac{1}{2} {k}_{1} {P}_{INV} .$$

The architecture of Lowy also requires k₁ XOR gates, but each one of these is connected to the drains of N minimum sized transistors (switches). Therefore, the power dissipated by the architecture in Lowy is given by:

$${P}_{4 L} = \frac{1}{2} {k}_{1} {P}_{XOR} + \frac{N}{2} {k}_{1} {P}_{min} .$$

3.5 Total Power.

Since k₁ outputs are available each clock cycle, the frequency of operation can be reduced by a factor of k₁. Therefore, the total power consumed by the architecture of the present invention is:

$$P = \frac{1}{{k}_{1}} [ \begin{matrix}2 {P}_{FF} + 2 {P}_{AND} ( \frac{M}{{D}_{av}} ⌈ \frac{N}{{k}_{1}} ⌉ ) + {k}_{1} {MP}_{OR} + \\ \frac{1}{2} {k}_{1} {P}_{FF} ( 1 + \frac{{D}_{av}}{N} ) + \frac{1}{2} {k}_{1} {P}_{XOR} + \frac{1}{2} {k}_{1} {P}_{INV}\end{matrix} ]$$

In comparison the total power consumed by the Lowy architecture is given by:

$${P}_{L} = \frac{1}{{k}_{1}} [ \begin{matrix}2 {P}_{FF} + 2 {P}_{AND} ( {k}_{1} M + {k}_{1} ) + {k}_{1} {MP}_{OR} + \\ {k}_{1} {P}_{FF} + \frac{1}{2} {k}_{1} {P}_{XOR} + \frac{N}{2} {k}_{1} {P}_{min}\end{matrix} ]$$

To simplify calculations the values of P_{INV} and Pₘᵢₙ are ignored, Thus, the final expressions become the following.

$${P}_{ours} = \frac{1}{{k}_{1}} [ \begin{matrix}2 {P}_{FF} + 2 {P}_{AND} ( \frac{M}{{D}_{av}} ⌈ \frac{N}{{k}_{1}} ⌉ ) + {k}_{1} {MP}_{OR} + \\ \frac{1}{2} {k}_{1} {P}_{FF} ( 1 + \frac{{D}_{av}}{N} ) + \frac{1}{2} {k}_{1} {P}_{XOR}\end{matrix} ]$$

$${P}_{Lowy} = \frac{1}{{k}_{1}} [ \begin{matrix}2 {P}_{FF} + 2 {P}_{AND} ( {k}_{1} M + {k}_{1} ) + {k}_{1} {MP}_{OR} + \\ {k}_{1} {P}_{FF} + \frac{1}{2} {k}_{1} {P}_{XOR}\end{matrix} ]$$

The decrease in power dissipation is given by,

$${P}_{Lowy} - {P}_{ours} = \frac{1}{{k}_{1}} [ 2 {P}_{AND} ( {k}_{1} M + {k}_{1} - \frac{M}{{D}_{av}} ⌈ \frac{N}{{k}_{1}} ⌉ ) + \frac{1}{2} {k}_{1} {P}_{FF} ( 1 - \frac{{D}_{av}}{N} ) ]$$

In the next section an example is described of the above design.

4. Low Power LFSR Implementation of Example Polynomial.

This section describes an example of the architecture of the present invention and quantifies the gain obtained in terms of hardware and power for this example.

In this section an LFSR is constructed according to an embodiment of the present invention with characteristic polynomial 1+x³+x⁴+x⁷+x¹². Comparisons are also made with both the architecture of Lowy as well as the architecture of Hamid and Chen in terms of power dissipation and hardware complexity. Table 7 illustrates the LFSR for the polynomial 1+x³+x⁴+x⁷+x¹², and is similar to that of Table 6 which was constructed for the polynomial 1+x²+x⁵.

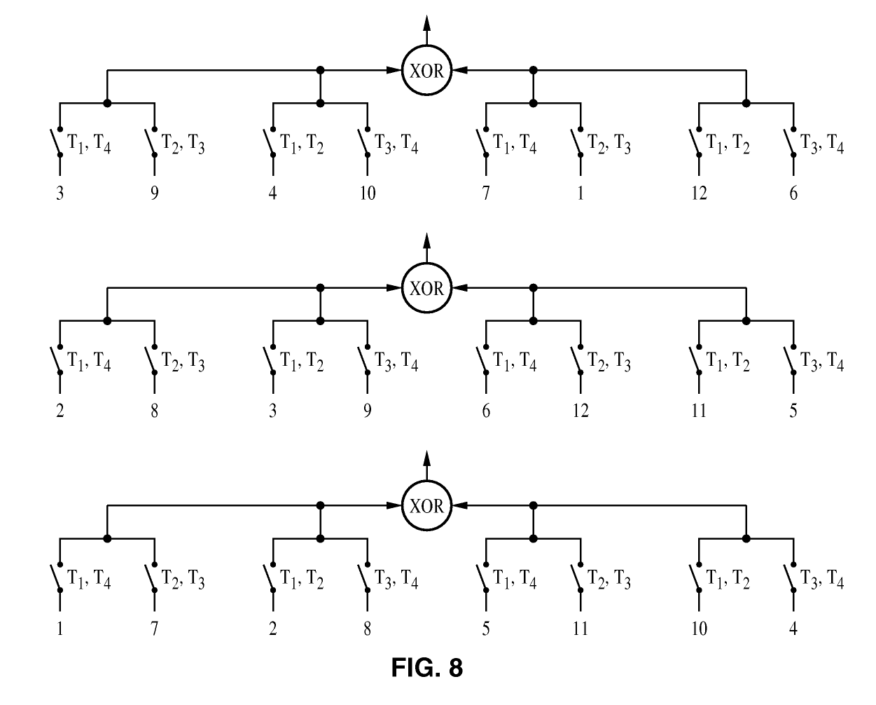

FIG. 8 illustrates an example LFSR circuit with XOR gates and their inputs constructed according to the invention based on Table 7. This LFSR produces three outputs every clock cycle. The LFSR requires a 4-phase generator, 4 2-input OR gates, 24 switches, 12 flip-flops, and 3 4-input XOR gates. Note that for this LFSR the value Dₐᵥ=8, because each row of the “flip-flops-XORed-row” in Table 7 has 8 distinct flip-flop outputs being XORed. For example there are 8 distinct terms in (3, 4, 7, 12), (12, 1, 4, 9), (9, 10, 1, 6), and (6, 7, 10, 3). Therefore, the average number of inputs an OR gate must have is

$$\frac{M}{{D}_{av}} ⌈ \frac{N}{{k}_{1}} ⌉ = \frac{4 \times 4}{8} = 2 ,$$

and the number of switches required by this LFSR is

$${k}_{1} {D}_{av} = {\sum }_{i = 1}^{{k}_{1}} {D}_{i} = 8 \times 3 = 24.$$

In contrast the Lowy architecture requires a 12-phase generator, 24 2-input OR gates, 60 switches, 12 flip-flops, and 3 4-input XOR gates.

The power dissipated by our architecture is given by

$${P}_{ours} = \frac{1}{3} ( 2 {P}_{FF} + 4 {P}_{AND} + 12 {P}_{OR} + \frac{5}{2} {P}_{FF} + \frac{3}{2} {P}_{XOR} ) .$$

In comparison, the power dissipated by Lowy's architecture is given by

$${P}_{Lowy} = \frac{1}{3} ( 2 {P}_{FF} + 30 {P}_{AND} + 12 {P}_{OR} + 3 {P}_{FF} + \frac{3}{2} {P}_{XOR} ) .$$

Therefore, the architecture of the present invention consumes less power, as given by

$${P}_{Lowy} - {P}_{ours} = \frac{1}{3} ( 26 {P}_{AND} + \frac{1}{2} {P}_{FF} ) .$$

5. Comparison of Power and Distinct Patterns Generated.

This section considers built-in self-test (BIST) applications for the LFSR according to the present invention as compared with the teachings of Hamid and Chen. The results of these tests indicate that the LFSR architecture of the present invention, despite operating with reduced hardware complexity, is capable of generating more distinct patterns than the architectures proposed by Hamid and Chen.

Polynomials of the type 1+x^{┌N/2┐}+x^{N} or 1+x^{┌N/2┐}+x^{N} are considered which are similar to the ones considered in the Hamid and Chen reference. It was shown in the Hamid and Chen reference that such polynomials result in a number of switches of order N, instead of the order (N+M) and that the number of distinct patterns generated is more than that of the Lowy architecture.

In comparison to this, the present invention can obtain N/2 outputs simultaneously, if N is odd, with hardware requirement that is less than that used in the Hamid and Chen reference. Since multiple outputs have been generated and the hardware required is less, the power consumption of the present inventive architecture is considerably less than that of Hamid and Chen. Accordingly, embodiments of the present invention generally provide more distinct patterns than generated by Hamid and Chen making the present invention more suitable for applications like BIST. It should be noted that for an even value of N the present invention does not generate as many distinct patterns as in the Hamid and Chen reference, however, the present design generates more distinct patterns if polynomials are used that are not of the form 1+x^{┌N/2┐}+x^{N} or 1+x^{┌N/2┐}+x^{N}.

For example if N is 10 one could use the polynomial 1+x³+x¹⁰ instead of 1+x⁵+x¹⁰. Using the data in Table 8 the hardware complexity and power dissipation equations can be obtained for polynomials of the kind 1+x^{┌N/2┐}+x^{N} or 1+x^{┌N/2┐}+x^{N} (N odd).

Using the general power equations described herein and putting in the appropriate value of k₁ and Dₐᵥ the power dissipation equations can be obtained. When

$${k}_{1} is ⌈ \frac{N}{2} ⌉ = \frac{N + 1}{2} ,$$

the power dissipation is given by the following.

$${P}_{ours} = \frac{N + 3}{2 N} {P}_{FF} + \frac{XOR}{2} + {MP}_{INV}$$

It should be noted that the phase generator in this embodiment requires only an inverter because only two phases are required. When k₁ is

$$⌊ \frac{N}{2} ⌋ = \frac{N + 1}{2} ,$$

the power dissipation is given by the following.

$${P}_{ours} = \frac{2}{N - 1} ( 2 {P}_{FF} + 2 {P}_{AND} ) + 2 {P}_{OR} + \frac{N + 4}{2 N} {P}_{FF} + \frac{{P}_{XOR}}{2}$$

In this case the phase generator consists of two flip-flops and two NOR gates. It is assumed that NOR gates and AND gates consume the same power. The above hardware complexity and power dissipation equations are compared to the LFSRs described by Hamid and Chen. In the architecture described in the reference by Hamid and Chen, to produce a single output requires an N-phase generator, (N+M) M-input OR gates, approximately N switches, N flip-flops and one XOR gate. For obtaining k₁ outputs the architecture in the Hamid and Chen reference requires k₁ XOR gates, 2k₁ N switches and k₁(N+2) OR gates.

The power dissipation equation for the Hamid and Chen architecture for a single output is

$$( 3 {P}_{FF} + 4 {P}_{AND} + 2 {P}_{OR} + \frac{1}{2} {P}_{XOR} )$$

and for k₁ outputs it is the same as for Lowy's case in the Hamid and Chen reference with M=2 and is given by

$$\frac{1}{{k}_{1}} ( 2 {P}_{FF} + 6 {k}_{1} {P}_{AND} + 2 {k}_{1} {P}_{OR} + {k}_{1} {P}_{FF} + \frac{1}{2} {k}_{1} {P}_{XOR} ) .$$

Consequently, the architecture of the present invention is superior both in terms of hardware complexity (less complex) and power dissipation over the currently preferred architectures. Table 9 compares power dissipation of present architecture with that of the Lowy reference and/or the Hamid and Chen reference, for different characteristic polynomials. The data used to obtain the table is for a CMOS 0.18 micron process standard cell library, with capacitances, C_{dff}=0.0027 pf, C_{XOR}=0.0042 pf, C_{OR}=0.0026 pf, C_{INV}=0.0027 pf, C_{AND}=00215 pf, and the power supply voltage is V_{dd} =1.8V with the frequency is set to 30 MHz.

From Table 9 it can be seen that on average the present architecture results in more than a 50% improvement in power dissipation when the number of outputs is greater than one. The first column of Table 9 lists the characteristic polynomial of the LFSR, the second column gives the power dissipated by either the Lowy architecture or Himad and Chen architecture, referred to as “conv.” for conventional, whichever provides lower dissipation for this instance, as given within the described references. The third column lists the power dissipated by the architecture of the present invention, listed as “ours”. Table 9 also compares in column four the percentage of the maximum of the number of distinct patterns that are generated by the architecture of the present invention with that generated by single output architectures in the Lowy reference or Himad and Chen reference for various polynomials. Columns five and six of Table 9 give the following quantity: number of distinct outputs in 2N cycles divided by 2N−1, which is the maximum number of distinct outputs possible. The entries in Column five are from either the Lowy reference or the Himad and Chen reference, whichever is higher. Column eight lists the best seeds of our architecture. A seed given in the table is an integer whose N -bit binary equivalent gives the initial values of the flip-flops. Therefore if the seed is

$${\sum }_{i = 1}^{N} {S}_{i} \times {2}^{i - 1} ,$$

then Sᵢ (1≦i≦N) is the binary value that the i^{th} flip-flop is initialized to. If several seeds result in the same maximum percentage then the smallest seed is given. The multiple output polynomials of the present invention are compared with previous single output architectures because the hardware overhead for previous architectures with multiple outputs is too high thus making them unusable. For some of the polynomials in Table 9 the present architecture results in a single output LFSR because k₁=1. From Column 6 of Table 9 it can be seen that the average percentage of the number of distinct patterns generated is close to 100%, thereby making our architecture suitable for BIST applications.

The present invention provides a new multiple-output LFSR architecture that results in lower hardware complexity and lower power dissipation than previously known architectures. The improvement provided by the present invention has been shown by way of specific examples and has been proven by deriving expressions for the number of hardware components and for the power dissipated. It has also been shown that the architecture of the invention can be used for BIST applications because of its ability to generate distinct patterns. The present invention can be utilized within a wide variety of applications.

Although the description above contains many details, these should not be construed as limiting the scope of the invention but as merely providing illustrations of some of the presently preferred embodiments of this invention. Therefore, it will be appreciated that the scope of the present invention fully encompasses other embodiments which may become obvious to those skilled in the art, and that the scope of the present invention is accordingly to be limited by nothing other than the appended claims, in which reference to an element in the singular is not intended to mean “one and only one” unless explicitly so stated, but rather “one or more.” All structural and functional equivalents to the elements of the above-described preferred embodiment that are known to those of ordinary skill in the art are expressly incorporated herein by reference and are intended to be encompassed by the present claims. Moreover, it is not necessary for a device or method to address each and every problem sought to be solved by the present invention, for it to be encompassed by the present claims. Furthermore, no element, component, or method step in the present disclosure is intended to be dedicated to the public regardless of whether the element, component, or method step is explicitly recited in the claims. No claim element herein is to be construed under the provisions of 35 U.S.C. 112, sixth paragraph, unless the element is expressly recited using the phrase “means for.”

TABLE 1
Operation of LFSR with Characteristic Polynomial 1 + x² + x⁵

| | Cycle Number | | | | |
|---|---|---|---|---|---|
| | 1 | 2 | 3 | 4 | 5 |
| Flip-Flop Outputs that | 2, 5 | 1, 4 | 5, 3 | 4, 2 | 3, 1 |
| are XORed | | | | | |
| Flip-flops into which the | 5 | 4 | 3 | 2 | 1 |
| XORed output is stored | | | | | |

TABLE 2
LFSR using Even Order Hamid's Polynomial 1 + x³ + x⁶

| | Cycle Number | | | | | |
|---|---|---|---|---|---|---|
| | 1 | 2 | 3 | 4 | 5 | 6 |
| XOR results of . . . | 3, 6 | 2, 5 | 1, 4 | 6, 3 | 5, 2 | 4, 1 |
| . . . stored at | 6 | 5 | 4 | 3 | 2 | 1 |

TABLE 3
LFSR using Odd Order Hamid's Polynomial 1 + x⁴ + x⁷

| | Cycle Number | | | | | | |
|---|---|---|---|---|---|---|---|
| | 1 | 2 | 3 | 4 | 5 | 6 | 7 |
| XOR results of . . . | 4, 7 | 3, 6 | 2, 5 | 1, 4 | 3, 7 | 2, 6 | 1, 5 |
| . . . stored at | 7 | 6 | 5 | 4 | 3 | 2 | 1 |

TABLE 4
Flip flop Updates for Polynomial 1 + x⁴ + x⁵ + x⁶ + x⁷

| | Cycle Number | | | | | | |
|---|---|---|---|---|---|---|---|
| | 1 | 2 | 3 | 4 | 5 | 6 | 7 |
| XOR results of . . . | 4, 5, | 3, 4, | 2, 3, | 1, 2, | 7, 1, | 7, 6, | 7, 6, |
| | 6, 7 | 5, 6 | 4, 5 | 3, 4 | 2, 3 | 2, 1 | 5, 1 |
| . . . stored at | 5 | 4 | 3 | 2 | 1 | 5 | 4 |

TABLE 5
Flip-flop Updates for Multiple Operations Polynomial 1 + x³ + x⁶

| | Cycle Number | | | | | |
|---|---|---|---|---|---|---|
| | 1 | | | 2 | | |
| XOR results of . . . | 3, 6 | 2, 5 | 1, 4 | 6, 3 | 5, 2 | 4, 1 |
| . . . stored at | 6 | 5 | 4 | 3 | 2 | 1 |

TABLE 6
Operation of Multiple Output LFSR with Polynomial 1 + x² + x⁵

| | New Cycle Number | | |
|---|---|---|---|
| | 1 | 2 | 3 |
| Flip-Flops XORed → | (2, 5) → 5 | (5, 3) → 3 | (3, 1) → 1 |
| destination flip-flop | (1, 4) → 4 | (4, 2) → 2 | |

TABLE 7
Operation of Multiple Output LFSR with Polynomial
1 + x³ + x⁴ + x⁷ + x¹²

| | Cycle Number | | | |
|---|---|---|---|---|
| | 1 | 2 | 3 | 4 |
| Flip-Flops | (3, 4, 7, | (12, 1, 4, | (9, 10, 1, | (6, 7, 10, |
| XORed → | 12) → 12 | 9) → 9 | 6) → 6 | 3) → 3 |
| destination FF | (2, 3, 6, | (11, 12, 3, | (8, 9, 12, | (5, 6, 9, |
| | 11) → 11 | 8) → 8 | 5) → 5 | 2) → 2 |
| | (1, 2, 5, | (10, 11, 2, | (7, 8, 11, | (4, 5, 8, |
| | 10) → 10 | 7) → 7 | 4) → 4 | 1) → 1 |

TABLE 8
Characteristics of LFSRs with Polynomial
1 + χ^{┌N/2┐} + χ^{N} or 1 + χ^{└N/2┘} + χ^{N}

| | k₁ = (N + 1)/2 | k₁ = (N − 1)/2 |
|---|---|---|
| Number of outputs | (N + 1)/2 | (N − 1)/2 |
| per cycle = k₁ | | |
| $Phases = ⌈ \frac{N}{{k}_{1}} ⌉$ | 2 | 3 |
| $Number of OR Gates = ⌈ \frac{N}{{k}_{1}} ⌉$ | 1 (since only 2 phases) | 3 |
| $\begin{matrix}Avg . No . Inputs to \\ each OR gate\end{matrix} = \frac{M}{{D}_{av}} ⌈ \frac{N}{{k}_{1}} ⌉$ | 4/3 | 3/2 |
| Maximum D | 3 | 4 |
| Number of switches = k₁ D | 3(N + 1)/2 | 4(N − 1)/2 |
| Number of OR gates = k₁ | (N + 1)/2 | (N − 1)/2 |
| Number of Flip-flops = N | N | N |

TABLE 9
Relative Power and Percent Comparison with Conventional LFSR

| | | | % | Conv. | Ours | % | Seed |
|---|---|---|---|---|---|---|---|
| | Conv. | Ours | im- | 2^{N} | | im- | from |
| Polynomial | Power (μW) | | proved | cycles (%) | | proved | Ours |
| 1 + x + x³ | 2.75 | 2.28 | 17.1 | 71.4 | 100 | 28.6 | 1 |
| 1 + x + x⁴ | 2.75 | 2.28 | 17.1 | 60.0 | 100 | 40.0 | 1 |
| 1 + x² + x⁵ | 2.33 | 1.42 | 39.1 | 25.8 | 100 | 74.2 | 1 |
| 1 + x + x⁶ | 2.75 | 2.28 | 17.1 | 46.0 | 62.3 | 16.3 | 1 |
| 1 + x⁴ + x⁷ | 2.33 | 0.915 | 60.73 | 26.8 | 100 | 73.2 | 1 |
| 1 + x⁴ + | 4.5 | 2.14 | 52.44 | 36.2 | 100 | 63.8 | 1 |
| x⁵ + x⁶ + | | | | | | | |
| x⁷ | | | | | | | |
| 1 + x + | 4.5 | 4.08 | 9.33 | 38.8 | 100 | 61.2 | 1 |
| x⁵ + x⁶ + | | | | | | | |
| x⁸ | | | | | | | |
| 1 + x⁴ + x⁹ | 2.33 | 1.135 | 51.3 | 40.9 | 100 | 59.1 | 1 |
| 1 + x³ + x¹⁰ | 2.4 | 1.33 | 44.6 | 45.9 | 100 | 54.1 | 1 |
| 1 + x³ + | 3.74 | 1.89 | 49.5 | N/A | 75.9 | N/A | 4 |
| x⁴ + x⁷ + | | | | | | | |
| x¹² | | | | | | | |

What is claimed is:

1. An apparatus for generating a multiple output digital sequence, comprising:
a plurality of N flip-flops forming a linear feedback shift register (LFSR) having a characteristic polynomial, 1+x^{k}^{₁}+x^{k}^{₂}+ . . . +x^{k}^{_{M−1}}+x^{N}, with k₁<k₂< . . . <k_{M-1}<N and M taps; and
a plurality of gates coupled to select flip-flops in said LFSR based on combining the cycles of multiple flip-flops within the LFSR into flip-flop groups in which none of the outputs of the flip-flops within each flip-flop group are needed as input until subsequent cycles;
wherein a separate phase clock signal is connected to each said flip-flop, or group of flip-flops.

2. An apparatus as recited in claim 1:
wherein said multiple outputs comprises up to k₁ outputs in each clock cycle;
wherein a maximum of k₁ XOR gates are required for generating k₁ outputs;
wherein the LFSR is configured to be driven by a maximum of ┌N/k₁┐ phases from a phase generator; and
wherein the maximum of number of switches needed is less than (N+M), where M is the number of taps in the LFSR.

3. An apparatus as recited in claim 1, wherein said digital sequence is generated at reduced power levels in response to clocking said N flip-flops as need arises, instead of clocking the flip-flops in each clock cycle while only generating a single bit of information per clock cycle as in a conventional LFSR.

4. An apparatus as recited in claim 1, wherein said gates comprise exclusive-OR (XOR) gates.

5. An apparatus as recited in claim 1, further comprising a multiplexer circuit coupled to said multiple outputs for generating a single output.

6. An apparatus as recited in claim 1, wherein the data inputs of at least two different flip-flops within said LFSR are driven by the outputs of at least two different gates.

7. An apparatus as recited in claim 1, wherein outputs of at least two of the LFSR flip-flops are available simultaneously.

8. An apparatus as recited in claim 1, further comprising digital switches for routing flip-flop outputs to gate inputs, or for selecting outputs when the gates are permanently coupled to the flip flops, or for a combination of routing flip-flop outputs to gate inputs and selecting outputs.

9. An apparatus as recited in claim 8:
wherein using the digital switches for selecting outputs is used in combination with permanently coupling exclusive-OR (XOR) gates to the flip-flops; and
wherein a maximum of N/2 XOR gates are required to implement an even order Hamid polynomial, while any arbitrary polynomial can be implemented with a maximum of N exclusive-OR gates.

10. An apparatus as recited in claim 1, wherein the combining of flip-flops into flip-flop groups allows slowing the clock rate to the LFSR in response to the fewer number of phases necessary or in response to having the outputs from multiple flip-flops available simultaneously.

11. An apparatus for generating a digital sequence, comprising:
a plurality of N flip-flops forming a linear feedback shift register (LFSR) having a characteristic polynomial, 1+x^{k}^{₁}+x^{k}^{₂}+ . . . +x^{k}^{_{M−1}}+x^{N}, with k₁<k₂< . . . <k_{M-1}<N and M taps for up to k₁ outputs in each clock cycle;
at least one switch coupled to the output of each said flip-flop;
a plurality of exclusive-OR (XOR) gates receiving inputs through said switches from said flip-flops and having outputs coupled to the data inputs of said flip-flops; and
at least two separate phase clock signals coupled to the clock inputs of flip-flops, the number of necessary phase clocks and the connection of the phase clocks to the clock inputs determined in response to combining the cycles for multiple flip-flops when none of the outputs of those multiple flip-flops are needed as input until subsequent cycles.

12. An apparatus as recited in claim 11, wherein the combination of cycles reduces the clock rate and lowers power dissipation.

13. An apparatus as recited in claim 11:
wherein a maximum of k₁ XOR gates are required for generating k₁ outputs;
wherein the LFSR is configured to be driven by a maximum of ┌N/k₁┐ phases from a phase generator; and
wherein the maximum number of switches required to implement the LFSR is less than (N+M), where M is the number of taps in the LFSR.

14. An apparatus as recited in claim 11, wherein the outputs of at least two different XOR gates drive the data inputs of at least two different flip-flops within said LFSR.

15. An apparatus as recited in claim 11, further comprising a multiplexer for selecting a single output from said LFSR.

16. An apparatus as recited in claim 11:
wherein said separate clocks comprise a first clock signal and a second clock signal;
wherein said second clock signal is the inverse of said first clock signal; and
wherein an N -phase clock generator is not necessary for driving said separate clock signals.

17. A method of generating a digital sequence, comprising:
forming N flip-flops for interconnection into a linear feedback shift register (LFSR) having a characteristic polynomial, 1+x^{k}^{₁}+x^{k}^{₂}+ . . . +x^{k}^{_{M−1}}+x^{N}, with k₁<k₂< . . . <k_{M-1}<N and M taps for k₁ outputs in each clock cycle;
determining the flip-flop outputs that are XORed and into which flip-flop the XOR output is stored for each clock cycle;
grouping the flip-flops by combining every k₁ clock cycles into one clock cycle so that each clock cycle produces k₁ outputs;
forming a switch network for each of the k₁, M-input XOR gates;
interconnecting the XOR gates and switches in response to said grouping; and
generating phase clocks for driving the clocks in each flip-flop group and control signals for activating any switches which are common between said phase clocks.

18. A method as recited in claim 17, wherein at least one switch is coupled between the output of each said flip-flop and the input of at least one said XOR gate.

19. A method as recited in claim 17, wherein said control signals are generated by ORing said phase clocks for driving the state of said switches.

20. A method as recited in claim 17:
wherein a maximum of k₁ XOR gates are required for generating said k₁ outputs;
wherein the LFSR is configured to be driven by maximum of ┌N/k₁┐ phase clocks; and
wherein the maximum number of switches required to implement the LFSR is less than (N+M), where M is the number of taps in the LFSR having N flip-flops.
